(19) United States
(12) Patent Application Publication
(10) Pub. No.: US 2026/0301809 A1
(43) Pub. Date: Oct. 1, 2026

(54) MEMORY DEVICE AND OPERATING METHOD OF THE SAME

(71) Applicant: SK Hynix Inc., Icheon-si (KR)

(72) Inventor: Jang Gun KIM, Icheon-si (KR)

(21) Appl. No.: 19/356,731

(22) Filed: Oct. 13, 2025

(30) Foreign Application Priority Data
Mar. 27, 2025 (KR) 10-2025-0039505

(51) Int. Cl. G11C 13/00

(52) U.S. Cl. CPC G11C 13/0069; G11C 13/0026; G11C 13/0061

(57) ABSTRACT

An operating method of a memory device includes receiving a first write command and a first address, confirming whether the first address designates a first normal memory cell of a specific region, and confirming that the first address designates the first normal memory cell of the specific region and turning on the first normal memory cell and a dummy memory cell.

### CROSS-REFERENCE TO RELATED APPLICATION

This application claims priority under 35 U.S.C. §119(a) to Korean Patent Application No. 10-2025-0039505, filed in the Korean Intellectual Property Office on Mar. 27, 2025, the entire contents of which are incorporated herein by reference.

### BACKGROUNDN

### Technical Field

Embodiments relate to an integrated circuit technology and, more particularly, to a memory device and an operating method of the same.

### Related Art

Recently, as an electronic device is reduced in size, has lower power consumption and higher performance, and is diversified, memory capable of storing information is required for various electronic devices, such as computers and portable communication devices. Furthermore, research on memory having various characteristics continues to be conducted.

Memory that is being researched also includes memory capable of storing data by using a characteristic in which the memory switches between different resistance states depending on a voltage or current thereto. Such memory includes resistive random access memory (RRAM), phase change random access memory (PRAM), ferroelectric random access memory (FRAM), magnetic random access memory (MRAM), an E-fuse, and selector only memory (SOM).

### SUMMARY

In an embodiment, an operating method of a memory device may include receiving a first write command and a first address, confirming whether the first address designates a first normal memory cell of a specific region, and confirming that the first address designates the first normal memory cell of the specific region and turning on the first normal memory cell and a dummy memory cell.

In an embodiment, a memory device may include a data storage region comprising a plurality of normal memory cells, a dummy region comprising a plurality of dummy memory cells, and a decoding circuit configured to turn on at least one of one normal memory cell, among the plurality of normal memory cells, and one dummy memory cell, among the plurality of dummy memory cells, in response to an address.

### BRIEF DESCRIOTION OF THE DRAWINGS

FIG. 1 is a diagram for describing a memory cell of a memory device according to an embodiment of the present disclosure.

FIG. 2 is a diagram for describing an operation of a memory device according to an embodiment of the present disclosure.

FIGS. 3A, 3B, 4A, and 4B are timing diagrams for describing the operation described with reference to FIG. 2 in detail.

FIG. 5 is a diagram for describing an operation of a memory device according to another embodiment of the present disclosure.

FIG. 6 is a diagram for describing a structure of a memory device according to an embodiment of the present disclosure.

FIG. 7 is a flowchart for describing an operating method of a memory device according to an embodiment of the present disclosure.

### DETAILED DESCRIPTION

Hereinafter, embodiments according to the technical spirit of the present disclosure are described with reference to the accompanying drawings.

Embodiments of the present disclosure relate to a technology for reducing a spike current generated when a memory cell is turned on. According to the embodiment, it is possible to improve the endurance of a memory cell and to increase the lifespan of a memory cell.

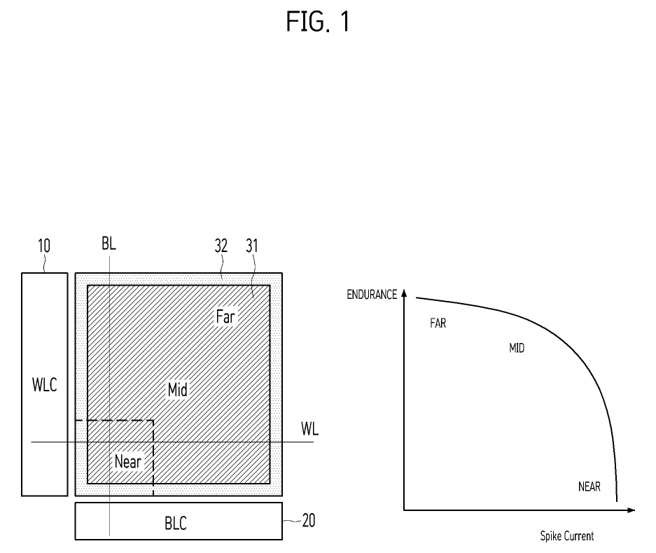

FIG. 1 is a diagram for describing a memory cell of a memory device according to an embodiment of the present disclosure.

Referring to FIG. 1, the memory device may include a word line contact region (WLC) 10, a bit line contact region (BLC) 20, and a data storage region 31. In this case, the memory device may further include a dummy region 32 that surrounds the data storage region 31.

The word line contact region 10 may be electrically connected to at least one word line WL. In this case, a voltage having a set level may be applied to a selected word line WL through the word line contact region 10.

The bit line contact region 20 may be electrically connected to at least one bit line BL. In this case, a voltage having a set level may be applied to a selected bit line BL through the bit line contact region 20.

The data storage region 31 may include at least one memory cell (not illustrated) that is electrically connected between the selected word line WL and the selected bit line BL. In this case, the memory cell may be turned on by a difference between voltage levels of the selected word line WL and the selected bit line BL. That is, when the difference between the voltage levels of the selected word line WL and the selected bit line BL is equal to or greater than a threshold voltage level of the memory cell, the memory cell may be turned on. On the other hand, when the difference between the voltage levels of the selected word line WL and the selected bit line BL is lower than the threshold voltage level of the memory cell, the memory cell may be turned off.

In order to turn on the memory cell in the data storage region 31, a voltage is applied to the word line WL through the word line contact region 10, and a voltage is applied to the bit line BL through the bit line contact region 20.

Accordingly, in the data storage region 31, a memory cell located closer to the word line contact region 10 may experience a greater change in the voltage level applied through the word line WL, due to a reduction in the resistance component of the word line WL. Similarly, a memory cell located closer to the bit line contact region 20 may experience a greater change in the voltage level applied through the bit line BL, due to a reduction in the resistance component of the bit line BL.

As a result, a memory cell located closer to the word line contact region 10 and the bit line contact region 20 may experience a greater change in the voltage level.

For example, when a memory cell located in close proximity to both the word line contact region 10 and the bit line contact region 20 is turned on, the amount of spike current generated may be increased.

In FIG. 1, a region of memory cells for which the sum of distances from the word line contact region 10 and the bit line contact region 20 is less than a first set distance is classified as a first region, referred to as a near region (Near). A region of memory cells for which the sum of distances from the word line contact region 10 and the bit line contact region 20 is greater than the first set distance and less than or equal to a second set distance is classified as a second region, referred to as a middle region (Mid). A region of memory cells for which the sum of distances from the word line contact region 10 and the bit line contact region 20 is greater than the second set distance is classified as a third region, referred to as a far region (Far).

The spike current characteristics of memory cells classified into the first region (Near), the second region (Mid), and the third region (Far) are described below. It may be seen that memory cells in the first region (Near) generate the largest spike current when turned on, while memory cells in the third region generate the smallest.

The spike current may affect the lifespan and endurance of a memory cell. For example, an increase in spike current can lead to a reduction in both the lifespan and endurance of the memory cell.

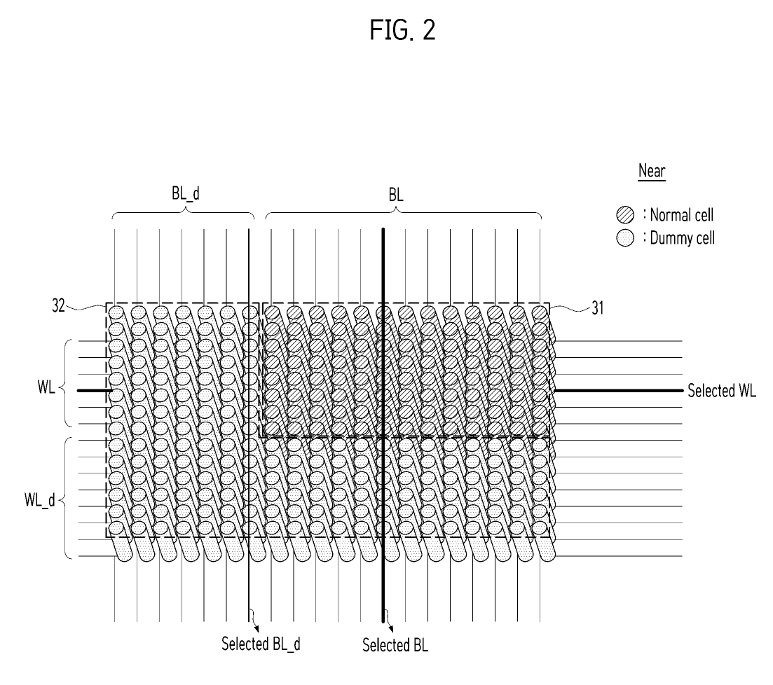

An operation and structure of the memory device, designed to increase the lifespan and endurance of memory cells based on their location characteristics as described above, will be described with reference to FIGS. 2-7, in accordance with an embodiment of the present disclosure.

FIG. 2 is a diagram for describing an operation of a memory device according to an embodiment of the present disclosure.

FIG. 2 may illustrate a first region (Near) 31 and a dummy region 32 adjacent to the first region (Near).

The first region (Near) 31 may include a plurality of normal memory cells (Normal cells) that are connected between a plurality of normal bit lines BL and a plurality of normal word lines WL.

The dummy region 32 may include a first plurality of dummy memory cells (Dummy cells) that are connected between a plurality of dummy bit lines BL_d and the plurality of normal word lines WL, a second plurality of dummy memory cells that are connected between the plurality of dummy bit lines BL_d and a plurality of dummy word lines WL_d, and a third plurality of dummy memory cells that are connected between the plurality of normal bit lines BL and the plurality of dummy word lines WL_d.

The operation of the memory device is described as follows. In this case, a target memory cell for a write or read operation may be one of the plurality of normal memory cells (Normal cells) in the first region (Near) 31.

One normal bit line, among the plurality of normal bit lines BL, may be selected as a selected normal bit line Selected BL based on an address during the write or read operation.

Furthermore, one normal word line, among the plurality of normal word lines WL, may be selected as a selected normal word line Selected WL based on an address during the write or read operation.

A normal memory cell that is connected between the selected normal bit line Selected BL and the selected normal word line Selected WL may be the target memory cell in which data is stored during the write operation, or may be the target memory cell from which data is read in the read operation.

In this case, one dummy bit line, among the plurality of dummy bit lines BL_d, may be selected as a selected dummy bit line Selected BL_d.

Accordingly, a dummy memory cell that is connected between the selected normal word line Selected WL and the selected dummy bit line Selected BL_d may be selected.

As described above, the memory device according to the embodiment of the present disclosure may be configured to select a dummy memory cell when a normal memory cell in the first region (Near) 31 is selected as a target memory cell during a write or read operation. In this case, the selected dummy memory cell may be electrically connected between the selected dummy bit line and the selected normal word line that is electrically connected to the selected normal memory cell.

As described above, the memory device according to the embodiment of the present disclosure can distribute a spike current that is generated when the selected normal memory cell is turned on to the selected dummy memory cell by additionally selecting the dummy memory cell when the normal memory cell in the first region (Near) 31 is selected during the write or read operation.

Accordingly, it is possible to mitigate the reduction in endurance of the selected normal memory cell caused by the spike current.

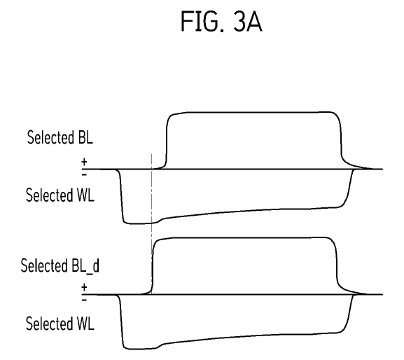

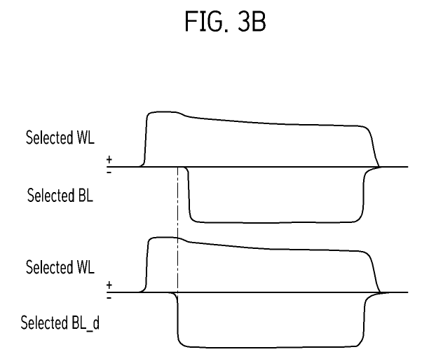

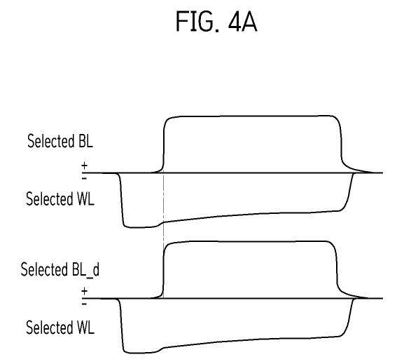

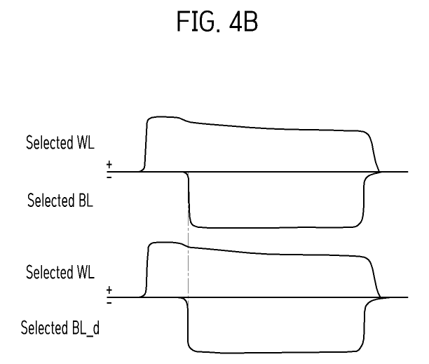

FIGS. 3A, 3B, 4A, and 4B are timing diagrams for describing the operation described with reference to FIG. 2 in detail.

FIGS. 3A and 3B may be timing diagrams of the selected normal bit line Selected BL, the selected normal word line Selected WL, and the selected dummy bit line Selected BL_d when the normal memory cell in the first region (Near) is selected during the write or read operation.

Referring to FIG. 3A, a first voltage (-) may be applied to the selected normal word line Selected WL, and a second voltage (+) may be then applied to the selected dummy bit line Selected BL_d. Thereafter, the second voltage (+) may be applied to the selected normal bit line Selected BL. In this case, the first voltage (-) may be a voltage having a lower level than the second voltage (+). The first voltage (-) may be a negative voltage, and the second voltage (+) may be a positive voltage. Furthermore, a difference between the levels of the first voltage (-) and the second voltage (+) may correspond to a voltage level sufficient to turn on the selected normal memory cell.

By applying the second voltage (+) to the selected dummy bit line Selected BL_d before applying the second voltage (+) to the selected normal bit line Selected BL, the selected dummy memory cell that is connected between the selected normal word line Selected WL and the selected dummy bit line Selected BL_d may be turned on before the selected normal memory cell that is connected between the selected normal word line Selected WL and the selected normal bit line Selected BL is turned on.

Referring to FIG. 3B, the second voltage (+) may be applied to the selected word line Selected WL, and the first voltage (-) may be then applied to the selected dummy bit line Selected BL_d. Thereafter, the first voltage (-) may be applied to the selected normal bit line Selected BL.

By applying the first voltage (-) to the selected dummy bit line Selected BL_d before applying the first voltage (-) to the selected normal bit line Selected BL , the selected dummy memory cell that is connected between the selected normal word line Selected WL and the selected dummy bit line Selected BL_d may be turned on before the selected normal memory cell that is connected between the selected normal word line Selected WL and the selected normal bit line Selected BL is turned on.

As a result, FIGS. 3A and 3B may describe operations in which when the normal memory cell in the first region (Near) is selected, the selected dummy memory cell is turned on earlier than the selected normal memory cell. Although not illustrated in FIGS. 3A and 3B, the selected dummy memory cell may be turned on after the selected normal memory cell by applying the voltage to the selected dummy bit line Selected BL_d later than the voltage applied to the selected normal bit line Selected BL.

FIGS. 4A and 4B may be timing diagrams of the selected normal bit line Selected BL, the selected normal word line Selected WL, and the selected dummy bit line Selected BL_d when the normal memory cell in the first region (Near) is selected during the write or read operation.

Referring to FIG. 4A, after the first voltage (-) is applied to the selected word line Selected WL, the second voltage (+) may be applied to the selected dummy bit line Selected BL_d and the selected normal bit line Selected B simultaneously. In this case, the first voltage (-) may have a lower level than the second voltage (+). The first voltage (-) may be a negative voltage, and the second voltage (+) may be a positive voltage. Furthermore, a difference between the levels of the first voltage (-) and the second voltage (+) may correspond to a voltage level sufficient to turn on the selected normal memory cell.

At this timing, the dummy memory cell that is connected between the selected normal word line Selected WL and the selected dummy bit line Selected BL_d may be turned on. Simultaneously, the normal memory cell connected between the selected normal word line Selected WL and the selected normal bit line Selected BL may also be turned on.

Referring to FIG. 4B, after the second voltage (+) is applied to the selected word line Selected WL, the first voltage (-) may be applied to the selected dummy bit line Selected BL_d and the selected normal bit line Selected BL simultaneously.

At this timing, the dummy memory cell that is connected between the selected normal word line Selected WL and the selected dummy bit line Selected BL_d may be turned on. Simultaneously, the normal memory cell that is connected between the selected normal word line Selected WL and the selected normal bit line Selected BL may also be turned on.

As a result, FIGS. 4A and 4B may describe operations in which when the normal memory cell in the first region (Near) is selected, the normal memory cell and the dummy memory cell are turned on simultaneously.

FIGS. 3A and 3B may be diagrams for describing that when the normal memory cell in the first region (Near) is selected, the turn-on timing of the selected normal memory cell and the turn-on timing of the selected dummy memory cell may be different from each other.

In the meantime, FIGS. 4A and 4B may be diagrams for describing when the normal memory cell in the first region (Near) is selected, the turn-on timing of the selected normal memory cell and the turn-on timing of the selected dummy memory cell may be the same.

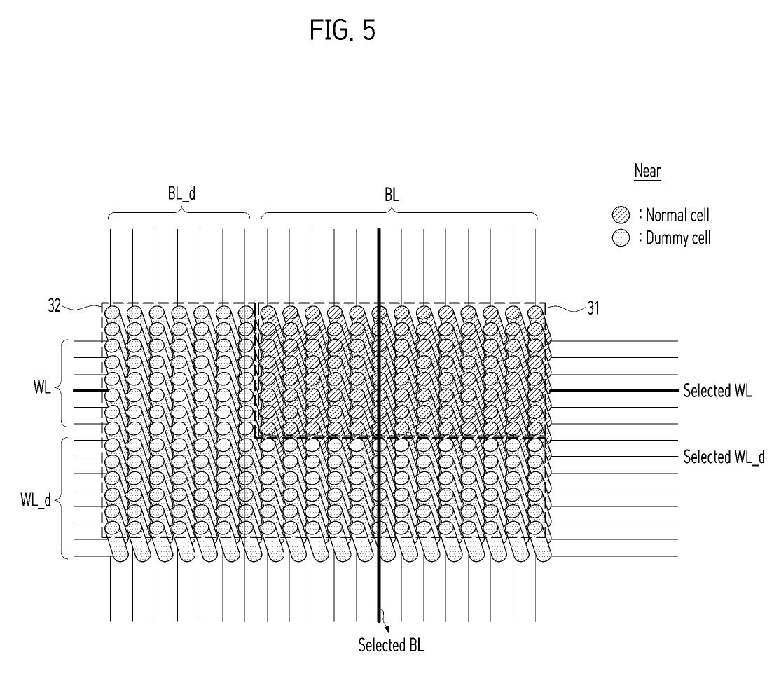

FIG. 5 illustrates a first region (Near) 31 and a dummy region 32 adjacent to the first region (Near) 31.

The first region (Near) 31 may include a plurality of normal memory cells that are connected between a plurality of normal bit lines BL and a plurality of normal word lines WL.

The dummy region 32 adjacent to the first region (Near) 31 may include a first plurality of dummy memory cells (Dummy cells) that are connected between a plurality of dummy bit lines BL_d and the plurality of normal word lines WL, a second plurality of dummy memory cells that are connected between the plurality of dummy bit lines BL_d and a plurality of dummy word lines WL_d, and a third plurality of dummy memory cells that are connected between the plurality of normal bit lines BL and the plurality of dummy word lines WL_d.

The operation of the memory device is described as follows. In this case, a target memory cell for a write or read operation may be one of the plurality of normal memory cells (Normal cells) in the first region (Near) 31.

One normal bit line, among the plurality of normal bit lines BL, may be selected as a selected normal bit line Selected BL based on an address during the write or read operation.

Furthermore, one normal word line, among the plurality of normal word lines WL, may be selected as a selected normal word line Selected WL based on an address during the write or read operation.

A normal memory cell that is connected between the selected normal bit line Selected BL and the selected normal word line Selected WL may be the target memory cell in which data is stored during the write operation, or may be the target memory cell from which data is read during the read operation.

In this case, one dummy word line, among the plurality of dummy word lines WL_d, may be selected as a selected dummy word line Selected WL_d.

Accordingly, a dummy memory cell that is connected between the selected normal bit line Selected BL and the selected dummy word line Selected WL_d may be selected.

As described above, the memory device according to the other embodiment of the present disclosure may be configured to select a dummy memory cell when a normal memory cell in the first region (Near) 31 is selected as a target memory cell during a write or read operation. In this case, the selected dummy memory cell may be electrically connected between the selected dummy word line and the selected normal bit line that is electrically connected to the selected normal memory cell.

As described above, the memory device according to the other embodiment of the present disclosure can distribute a spike current that is generated when the selected normal memory cell is turned on to the selected dummy memory cell by additionally selecting the dummy memory cell when the normal memory cell in the first region (Near) 31 is selected during the write or read operation.

Accordingly, it is possible to mitigate the reduction in endurance of the selected normal memory cell caused by the spike current.

The operation of the memory device illustrated in FIG. 5 may adjust the turn-on timing of the selected normal memory cell and the turn-on timing of the selected dummy memory cell either differently or identically by adjusting the timing of a voltage applied to the selected normal word line Selected WL and the selected dummy word line Selected WL_d, in a manner similar to that described with reference to FIGS. 3A, 3B, 4A, and 4B.

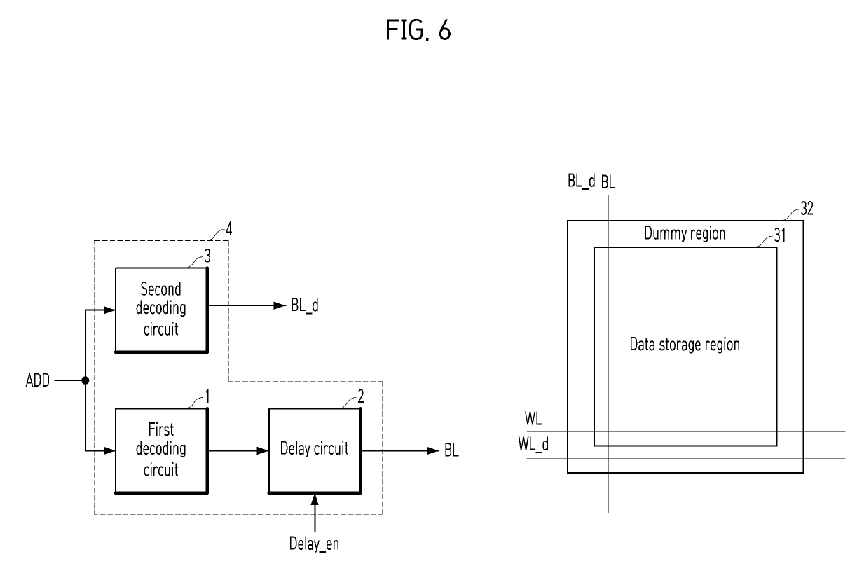

FIG. 6 is a diagram for describing a structure of a memory device according to an embodiment of the present disclosure.

Referring to FIG. 6, the memory device may include a data storage region 31, a dummy region 32, and a decoding circuit 4. In this case, as illustrated in FIGS. 2 and 5, the data storage region 31 may include a plurality of normal word lines WL and a plurality of normal bit lines BL. The dummy region 32 may include the plurality of normal word lines WL, the plurality of normal bit lines BL, a plurality of dummy word lines WL_d, and a plurality of dummy bit lines BL_d.

The data storage region 31 may include a plurality of normal memory cells. Each of the plurality of normal memory cells may be connected between a corresponding normal bit line BL and a corresponding normal word line WL.

The dummy region 32 may include a first plurality of dummy memory cells connected between the normal bit lines BL and the dummy word lines WL_d, a second plurality of dummy memory cells connected between the dummy bit lines BL_d and the normal word lines WL, and a third plurality of dummy memory cells connected between the dummy bit lines BL_d and the dummy word lines WL_d.

The decoding circuit 4 may include a first decoding circuit 1, a second decoding circuit 3, and a delay circuit 2. The first decoding circuit 1 may be referred to as a normal decoding circuit. The second decoding circuit 3 may be referred to as a dummy decoding circuit.

The normal decoding circuit 1 may select one normal bit line, among the plurality of normal bit lines, by decoding an address ADD. At this time, the selected normal bit line may be driven by applying the first voltage (-) or the second voltage (+) to the selected normal bit line.

The delay circuit 2 may delay the driving of the selected normal bit line. In this case, the delay circuit 2 may delay the driving of the selected normal bit line when a delay enable signal Delay_en is enabled, and may operate so that the selected normal bit line is driven without delay when the delay enable signal Delay_en is disabled.

The dummy decoding circuit 3 may be configured to select one dummy bit line BL_d, among the plurality of dummy bit lines, when the address ADD has a value that selects a normal memory cell in the first region (Near). For example, the dummy decoding circuit 3 may select the one dummy bit line, among first to tenth dummy bit lines, e.g., the third dummy bit line, when the address ADD that selects the normal memory cell in the first region (Near) is input, that is, when the address ADD has a value within a specific range.

Accordingly, the memory device according to the embodiment of the present disclosure may select the normal bit line BL and the dummy bit line BL_d when receiving the address ADD that selects the normal memory cell in the first region (Near) during a write or read operation. In the memory device according to the embodiment of the present disclosure, only a normal bit line BL may be selected when an address is received that designates a normal memory cell in a region other than the first region (Near), such as the middle region (Mid) or the far region (Far), during a write or read operation.

FIG. 6 illustrates that a normal bit line BL and a dummy bit line BL_d are selected when an address that selects a normal memory cell in the first region (Near) is received during a write or read operation. However, it is to be noted that, in the memory device according to the embodiment of the present disclosure, a normal word line WL and a dummy word line BL_d may be selected when an address is received that designates a normal memory cell in the first region (Near) during a write or read operation.

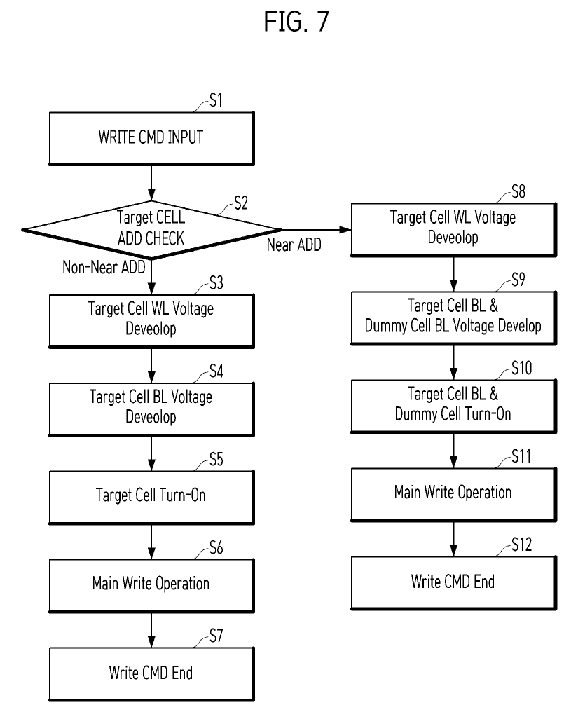

FIG. 7 is a flowchart for describing an operating method of a memory device according to an embodiment of the present disclosure.

Referring to FIG. 7, the operating method may include a write command reception process S1, an address confirmation process S2, a first word line voltage application process S3, a second bit line voltage application process S4, a first memory cell turn-on process S5, a first main write operation execution process S6, a first write operation end process S7, a second word line voltage application process S8, a second bit line voltage application process S9, a second memory cell turn-on process S10, a second main write operation execution process S11, and a second write operation end process S12.

The first write command reception process S1 may include a process of inputting a write command (CMD) to the memory device.

The address confirmation process S2 may include a process of determining whether an address received along with the write command is an address that designates a normal memory cell in the first region (Near) or an address that designates a normal memory cell in the second or third region (Mid or Far). When it is determined that the address received in the address confirmation process S2 is not the address that designates a normal memory cell in the first region (Near) (Non-Near ADD), the first word line voltage application process S3 may be performed.

On the other hand, when it is determined that the address received in the address confirmation process S2 is the address that designates a normal memory cell in the first region (Near) (Near ADD), the second word line voltage application process S8 may be performed.

The first word line voltage application process S3 is a process that is performed when it is determined that the received address does not designate a normal memory cell in the first region (Near) (Non-Near ADD), and may include a process of applying a first voltage to a selected normal word line in the second region (Mid) or the third region (Far).

The first bit line voltage application process S4 may include a process of applying a second voltage to a selected normal bit line in the second region or the third region. In this case, a difference between the levels of the first voltage and the second voltage may correspond to a voltage level sufficient to turn on a selected normal memory cell coupled between the selected normal word line and the selected normal bit line.

The first memory cell turn-on process S5 may include a process of turning on the selected normal memory cell that is connected between the selected normal word line and the selected normal bit line.

The first main write operation execution process S6 may include a process of changing a state of the turned-on normal memory cell to a state corresponding to a data level. For example, the first main write operation execution process S6 may include changing the state of the turned-on normal memory cell to a set state when the data level is a low level and changing the state of the turned-on normal memory cell to a reset state when the data level is a high level.

The first write operation end process S7 may include a process of terminating a write operation for the selected normal memory cell in the second region (Mid) or the third region (Far).

The second word line voltage application process S8 is a process that is performed when it is determined that the received address designates a normal memory cell in the first region (Near) (Near ADD), and may include a process of applying the first voltage to a selected normal word line in the first region (Near).

The second bit line voltage application process S9 may include a process of applying the second voltage to a selected normal bit line in the first region (Near) and one dummy bit line. In this case, a difference between the levels of the first voltage and the second voltage may correspond to a voltage level sufficient to turn on a normal memory cell.

The second memory cell turn-on process S10 may include a process of turning on the normal memory cell that is connected between the selected normal word line and the selected normal bit line and a dummy memory cell that is connected between the selected normal word line and a selected dummy bit line.

The second main write operation execution process S11 may include a process of changing a state of the turned-on normal memory cell, along with the dummy memory cell, to a state corresponding to a data level. For example, the second main write operation execution process S11 may include changing the state of the turned-on normal memory cell to a set state when the data level is a low level and changing the state of the turned-on normal memory cell to a reset state when the data level is a high level.

The second write operation end process S12 may include a process of terminating a write operation for the normal memory cell in the first region (Near).

FIG. 7 illustrates and describes an operating method of turning on a normal memory cell that is connected between a normal word line and a normal bit line and a dummy memory cell that is connected between the normal word line and a dummy bit line by applying a voltage to the normal bit line and the dummy bit line when an address designates a memory cell in the first region (Near). To change the operating method into an operating method of turning on a normal memory cell that is connected between a normal word line and a normal bit line and a dummy memory cell that is connected between a dummy word line and the normal bit line by applying a voltage to the normal word line and the dummy word line when an address designates a memory cell in the first region (Near) by using such an operating principle may be a simple design change for those skilled in the art.

FIG. 7 illustrates and describes an operating method of turning on a normal memory cell that is connected between a normal word line and a normal bit line and a dummy memory cell that is connected between the normal word line and a dummy bit line by applying a voltage to the normal bit line and the dummy bit line when an address designates a memory cell in the first region (Near). To change the operating method into an operating method of turning on a normal memory cell that is connected between a normal word line and a normal bit line and a dummy memory cell that is connected between a dummy word line and the normal bit line by applying a voltage to the normal word line and the dummy word line when an address designates a memory cell in the first region (Near) by using such an operating principle may be a simple design change for those skilled in the art.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. An operating method of a memory device, the method comprising:
receiving a first write command and a first address;
determining whether the first address designates a first normal memory cell in a specific region; and
in response to determining that the first address designates the first normal memory cell in the specific region, turning on the first normal memory cell and a dummy memory cell.

2. The operating method of claim 1, wherein the specific region comprises a region in which a sum of distances from a word line contact region and a bit line contact region to the first normal memory cell designated by the first address is less than a predetermined distance.

3. The operating method of claim 1, wherein turning on the first normal memory cell and the dummy memory cell comprises:
selecting a normal word line based on the first address;
selecting a normal bit line based on the first address; and
selecting a dummy bit line in response to determining that the first address designates the first normal memory cell in the specific region.

4. The operating method of claim 3, further comprising adjusting a timing at which a voltage is applied to the selected normal bit line and a timing at which the voltage is applied to the selected dummy bit line to be different from each other.

5. The operating method of claim 3, further comprising adjusting a timing at which a voltage is applied to the selected normal bit line and a timing at which the voltage is applied to the selected dummy bit line to be identical.

6. The operating method of claim 1, wherein turning on the first normal memory cell and the dummy memory cell comprises:
selecting a normal word line based on the first address;
selecting a normal bit line based on the first address; and
selecting a dummy word line in response to determining that the first address designates the first normal memory cell in the specific region.

7. The operating method of claim 6, further comprising adjusting a timing at which a voltage is applied to the selected normal word line and a timing at which the voltage is applied to the selected dummy word line to be different from each other.

8. The operating method of claim 6, further comprising adjusting a timing at which a voltage is applied to the selected normal word line and a timing at which the voltage is applied to the selected dummy word line to be identical.

9. The operating method of claim 1, further comprising:
receiving a second write command and a second address;
determining whether the second address designates a second normal memory cell in a region other than the specific region; and
in response to determining that the first address designates the second normal memory cell in the region other than the specific region, turning on the second normal memory cell.

10. The operating method of claim 9, wherein the region other than the specific region comprises a region in which a sum of distances from the word line contact region and the bit line contact region to the second normal memory cell designated by the second address is greater than a predetermined distance.

11. The operating method of claim 9, wherein turning on the second normal memory cell comprises:
selecting a normal word line based on the second address; and
selecting a normal bit line based on the second address.

12. A memory device comprising:
a data storage region comprising a plurality of normal memory cells;
a dummy region comprising a plurality of dummy memory cells; and
a decoding circuit configured to turn on at least one of one of the plurality of normal memory cells or one of the plurality of dummy memory cells, based on an address.

13. The memory device of claim 12, wherein the decoding circuit is configured to:
in response to determining that the normal memory cell that is selected based the address is a normal memory cell in a specific region of the data storage region, turn on the dummy memory cell that is selected based the address, and
in response to determining that the normal memory cell that is selected based on the address is a normal memory cell in a region other than the specific region, turning on no dummy memory cell.

14. The memory device of claim 13, wherein in response to determining that the normal memory cell that is selected based on the address is a normal memory cell in the specific region, the decoding circuit selects a normal bit line that is connected to the selected normal memory cell and selects a dummy bit line that is connected to the dummy memory cell selected based the address.

15. The memory device of claim 13, wherein in response to determining that the normal memory cell that is selected based on the address is a normal memory cell in the region other than the specific region, the decoding circuit selects only a normal bit line that is connected to the selected normal memory cell.

16. The memory device of claim 14, wherein the decoding circuit comprises:
a normal decoding circuit configured to select the normal bit line based on the address, and
a dummy decoding circuit configured to select the dummy bit line based on the address.

17. The memory device of claim 16, wherein the decoding circuit further comprises a delay circuit configured to adjust a driving timing of the selected normal bit line and a driving timing of the selected dummy bit line to be either identical or different.

18. The memory device of claim 17, wherein the delay circuit is configured to:
delay the driving timing of the selected normal bit line when a delay enable signal is enabled, and
bypass the delay of the driving timing of the selected normal bit line when the delay enable signal is disabled.

19. The memory device of claim 13, wherein in response to determining that the normal memory cell that is selected based on the address is the normal memory cell in the specific region of the data storage region, the decoding circuit selects a normal word line that is connected to the selected normal memory cell and selects a dummy word line that is connected to the dummy memory cell.

20. The memory device of claim 13, wherein in response to determining that the normal memory cell that is selected based on the address is the normal memory cell in the region other than the specific region, the decoding circuit selects only a normal word line that is connected to the selected normal memory cell.
